(19) United States
(12) Patent Application Publication
(10) Pub. No.: US 2022/0344297 A1
(43) Pub. Date: Oct. 27, 2022

(54) SEMICONDUCTOR PACKAGE INHIBITING VISCOUS MATERIAL SPREAD

(71) Applicant: INPHI CORPORATION, San Jose, CA (US)

(72) Inventors: Choong Kooi CHEE, San Jose, CA (US); Dwayne Richard SHIRLEY, San Jose, CA (US); Han GAO, San Jose, CA (US)

(21) Appl. No.: 17/239,327

(22) Filed: Apr. 23, 2021

(51) Int. Cl. H01L 23/00; H01L 23/367

(52) U.S. Cl. CPC H01L 24/26; H01L 23/3675; H01L 24/32; H01L 24/83; H01L 24/29; H01L 2224/26145; H01L 2224/26175; H01L 2224/32245; H01L 2224/29191; H01L 2224/83862; H01L 2224/83874; H01L 2224/83007; H01L 23/3737

(57) ABSTRACT

A semiconductor package includes spread inhibiting structure to constrain the movement of viscous material during fabrication. In some embodiments, the spread inhibiting structure comprises a recess in an underside of a package lid overlying the die. According to other embodiments, the spread inhibiting structure comprises polymer disposed on the lid underside proximate to a side of the packaged die. According to still other embodiments, the spread inhibiting structure comprises a polymer disposed around the top of the die to serve as a dam and contain spreading. In some embodiments, the viscous material may be a Thermal Integration Material (TIM) in an uncured state, and the polymer may be the TIM in a cured state.

### BACKGROUND

The present invention is directed to semiconductor packages.

Packages are utilized to surround semiconductor chips and provide communication thereto. Various different package types exist, such as lid-type packages and molded type packages.

A package may enclose not only a semiconductor die, but also adjacent features such as capacitors. During package fabrication viscous materials may be used, and the unwanted spread of such materials between package elements can lead to reduced reliability.

### SUMMARY

A semiconductor package includes spread inhibiting structure to constrain the movement of viscous material during fabrication. In some embodiments, the spread inhibiting structure comprises a recess in an underside of a package lid overlying the die. According to other embodiments, the spread inhibiting structure comprises polymer disposed on the lid underside proximate to a side of the packaged die. According to still other embodiments, the spread inhibiting structure comprises a polymer disposed around the top of the die to serve as a dam and contain spreading. In some embodiments, the viscous material may be a Thermal Integration Material (TIM) in an uncured state, and the polymer may be the TIM in a cured state.

Embodiments achieve these benefits and others in the context of known technology. However, a further understanding of the nature and advantages of the present invention may be realized by reference to the latter portions of the specification and attached drawings.

### BRIEF DESCRIPTION OF THE DRAWINGS

The following diagrams are merely examples, which should not unduly limit the scope of the claims herein. One of ordinary skill in the art would recognize many other variations, modifications, and alternatives. It is also understood that the examples and embodiments described herein are for illustrative purposes only and that various modifications or changes in light thereof will be suggested to persons skilled in the art and are to be included within the spirit and purview of this process and scope of the appended claims.

FIG. 1 is a simplified cross-sectional view illustrating fabrication of a package according to an embodiment.

FIG. 2 is a simplified flow diagram illustrating the fabrication of a package according to an embodiment.

FIG. 3 shows a simplified cross-sectional view of an exemplary embodiment of a package. FIG. 3A shows a plan view of the lid underside of the package of FIG. 3.

FIG. 4 shows a simplified cross-sectional view of another exemplary embodiment of a package. FIG. 4A shows a plan view of the lid underside of the package of FIG. 4.

FIG. 5 shows a simplified cross-sectional view of yet another exemplary embodiment of a package.

### DESCRIPTION

The present invention is directed to packaging of semiconductor devices.

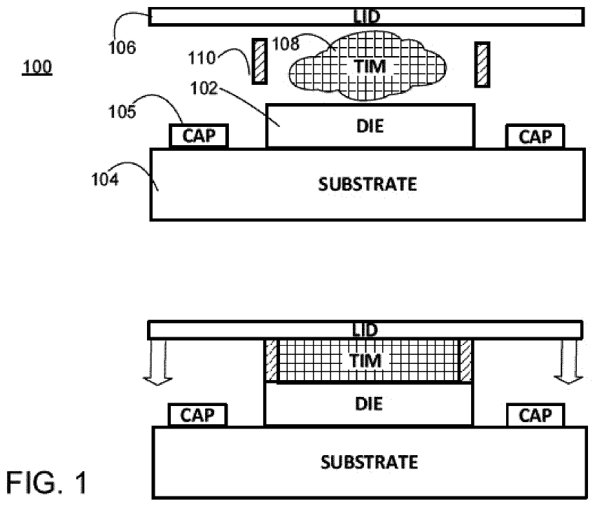

FIG. 1 is a simplified cross-sectional view illustrating fabrication of a semiconductor package according to an embodiment. Specifically, the package 100 includes a die 102 disposed in contact with a substrate 104. Capacitors 105 are also positioned on the substrate, proximate to the die.

A lid 106 fits over the die. (For ease of illustration, the sides of the lid are omitted from FIG. 1.)

A Thermal Interface Material (TIM) 108 is positioned on top of the die. The thermal conductivity characteristics of the TIM facilitate efficient communication of heat to the lid from the operating die. From the lid, the die can be dispersed into the environment.

As shown in FIG. 1, upon initial dispensing the TIM is exhibits a viscous state. Thus, upon fitting the lid down upon the die, the viscous TIM would be expected to spread laterally.

Unimpeded, such spreading could even extend to reach the adjacent capacitor(s). This result could adversely affecting the reliability in performance of the entire package.

To inhibit such unwanted lateral spread of viscous material, the package of FIG. 1 is equipped with a spread inhibitor structure 110. This spread inhibitor serves as a physical barrier to the spread of viscous TIM, containing it within the immediate vicinity of the die.

For purposes of illustration in FIG. 1, the spread inhibitor structure is initially shown as in contact with neither the package lid nor the die top surface. However as described in detail below, the spread inhibitor is generally provided in contact with the package lid or with the top surface of the die.

Once the lid has been pressed down upon the TIM, the TIM may be cured. This curing could be based upon exposure to applied energy, for example by heating the entire package.

Other forms of curing may involve the application of ultraviolet radiation or electron beams. There the package lid or substrate may be permeable to the applied energy.

One result of curing the viscous material, may be a change in viscosity. Now contained by the spread inhibitor, the cured and hardened material would not be expected to undergo additional spreading, even under exposure to heat given off by an operating die.

In some embodiments, the spread inhibitor may be present on the underside of the lid as the package is assembled. According to other embodiments, the spread inhibitor component may be present on the top surface of the die as the package is assembled.

As is discussed in detail below, the spread inhibitor component can take different forms, depending upon the particular embodiment. For example, in one specific embodiment the spread inhibitor can take the form of a recessed area located in an underside of the lid enclosing the die. Wall of the lid recess serve to contain the spread of viscous TIM.

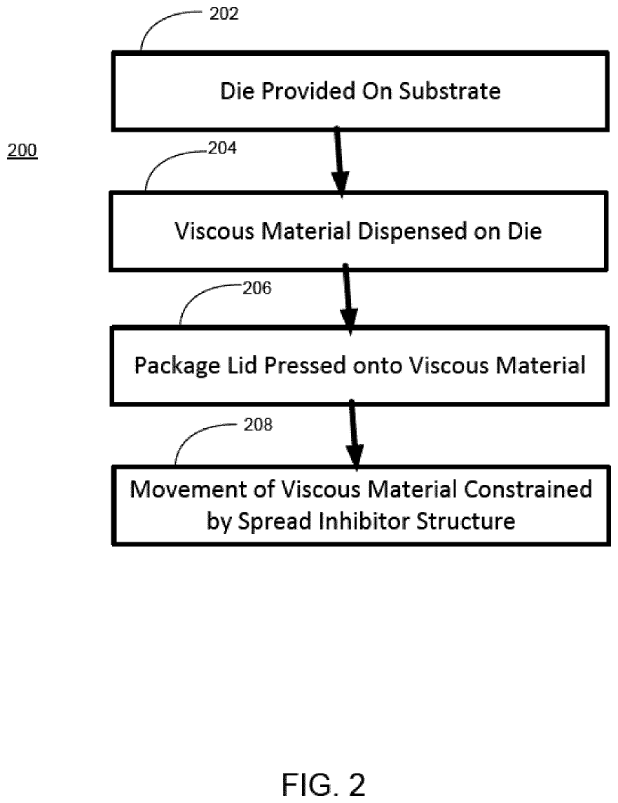

FIG. 2 is a simplified flow diagram illustrating a process 200 of fabricating a package according to an embodiment.

At 202, a die is provided on a substrate. At 204, viscous material is dispensed on top of the die.

At 206, a lid is pressed down onto the viscous material to enclose the die. At 208, a spread inhibitor contains the movement of the viscous material.

Embodiments of packages featuring spread inhibitors, may offer one or more benefits. One such benefit is reduced cost. In particular, the yield of reliable packages resulting from fabrication would be expected to increase. This is because flaws attributable to the unwanted spread of viscous material to contact adjacent structures (e.g., capacitors), may be reduced or eliminated.

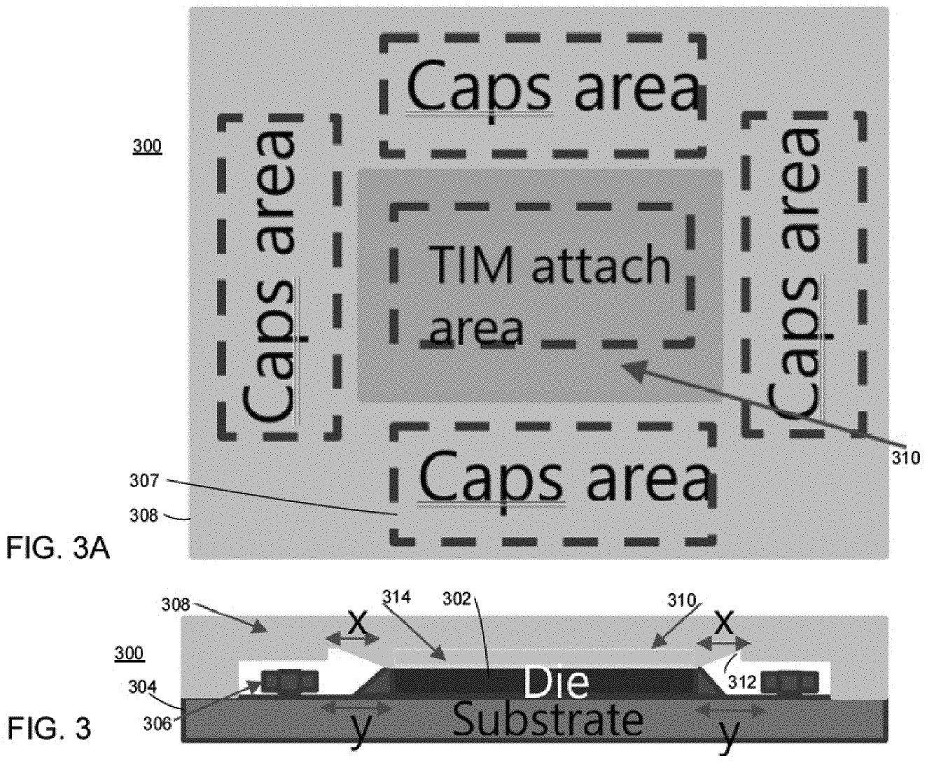

FIG. 3 shows a simplified cross-sectional view of an exemplary embodiment of a package 300. FIG. 3A shows a plan view of the lid underside of the package of FIG. 3.

In particular, the package comprises a die 302 attached to underlying substrate 304. Capacitors 306 are disposed on the substrate occupying areas 307, at a lateral distance “y” from the side of the die.

Here the spread inhibitor comprises a recess 310 in the package lid 308, that is located over the top of the die. The lid recess may have a depth of between about 50-100 μm.

The recess includes an even deeper moat 312, having a width “x” extending from the side of the die. Here, x<y.

During a package fabrication process, TIM 314 is dispensed onto the top of the die at TIM attach area 316. Then, the lid is pressed down onto the TIM.

TIM that spreads laterally as a result of its viscosity, spreads beyond the TIM attach area over the top of the die. TIM that spreads even further, flows into the recess and occupying the deeper moat feature. This contains the TIM and prevents it from flowing further (e.g., all the way to the capacitors).

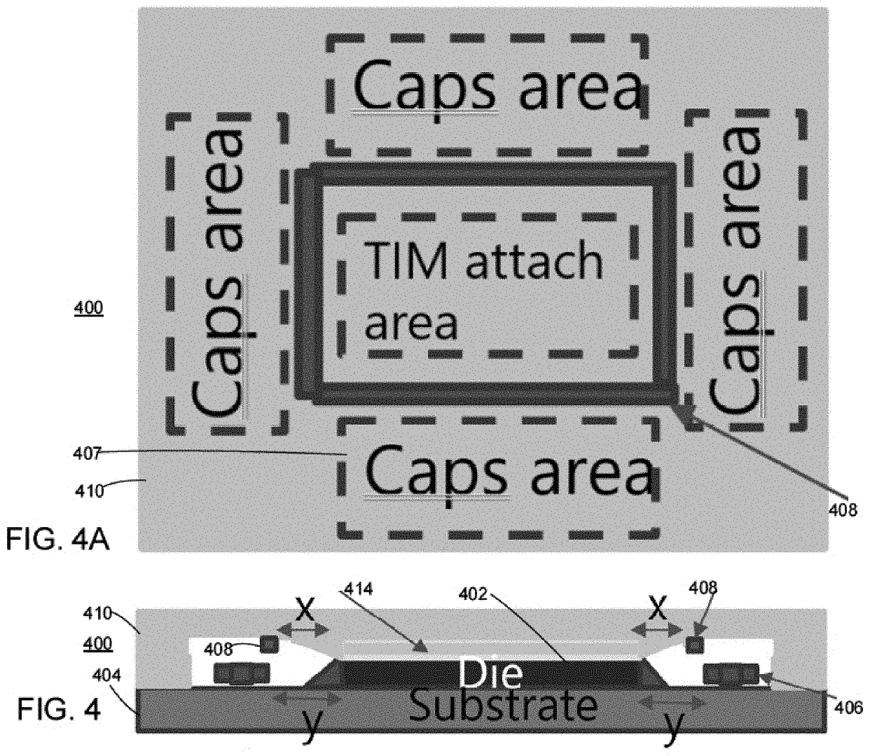

FIG. 4 shows a simplified cross-sectional view of another exemplary embodiment of a package 400. FIG. 4A shows a plan view of the lid underside of the package of FIG. 4.

In particular, the package comprises a die 402 attached to underlying substrate 404. Capacitors 406 are disposed on the substrate occupying areas 407, at a lateral distance “y” from the side of the die.

Here the spread inhibitor comprises a polymer stopper 408 in contact with the underside of lid 410. The polymer stopper has a thickness of between about 50-100 μm.

The polymer stopper begins at a distance “x” from the side of the die. Here, x<y.

During a package fabrication process, TIM 414 is dispensed onto the top of the die at TIM attach area 416. Then, the lid is pressed down onto the TIM.

TIM that spreads laterally as a result of its viscosity, spreads beyond the TIM attach area over the top of the die. TIM that spreads even further, encounters the polymer stopper and is halted. This contains the TIM and prevents it from flowing further (e.g., all the way to the capacitors).

The polymer stopper can comprise any polymer having desirable characteristic matching the parameters of the package fabrication process. In certain embodiments, the polymer stopper could even be formed from the same polymer as the TIM.

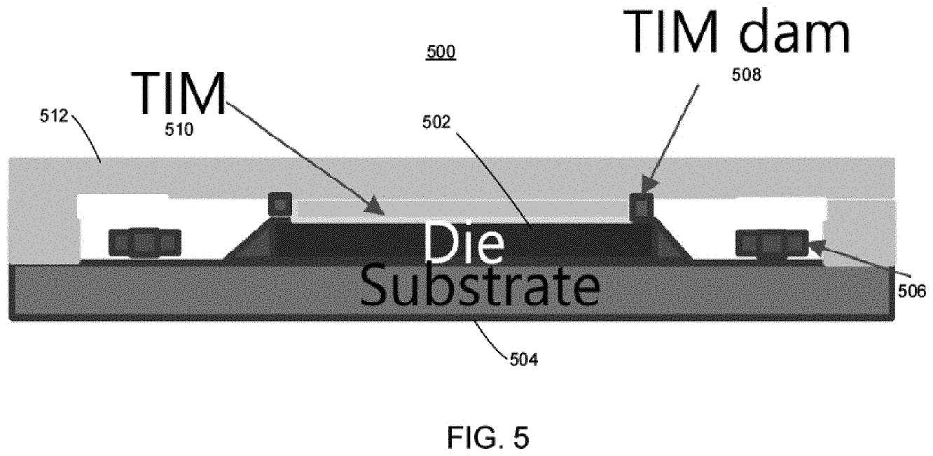

FIG. 5 shows a simplified cross-sectional view of yet another exemplary embodiment of a package. Package 500 comprises a die 502 attached to underlying substrate 504. Capacitors 506 are disposed on the substrate at a lateral distance from the side of the die.

Here the spread inhibitor comprises a TIM polymer dam 508 in contact with the top surface of the die. The TIM polymer dam is located at the side of the die, and is formed by a preliminary curing process.

During a package fabrication process, uncured TIM 510 is dispensed onto the top of the die. Then, the lid 512 is pressed down onto the uncured, viscous TIM.

TIM that spreads laterally as a result of its viscosity, moves beyond the initial TIM attach area over the top of the die. Then the uncured, viscous TIM encounters the cured TIM of the polymer dam and is halted. This contains the uncured, viscous TIM and prevents it from flowing further (e.g., all the way to the capacitors).

### Example

Concrete parameters of a package fabrication process are now provided in connection with the TIM dam embodiment. In this exemplary embodiment, the TIM material comprised silicone adhesive.

The TIM dam was formed by dispensing a band of TIM of width at a minimum of 10 μm and thickness 50-70 μm, selectively around the top surface of the die proximate to the die side. The TIM was dispensed at a temperature of 25° C. and exhibited a certain thixotropic index that can hold the shape of the dam.

Without the lid being applied, the dispensed TIM was cured. Here, the curing conditions comprised the application of thermal energy from an oven at a temperature of about 140-200° C. for a duration of about 1-3 hours.

This curing resulted in conversion of the dispensed TIM band, into a hardened TIM dam. The TIM dam exhibited a width of a minimum of 10 μm and thickness of 50-70 μm.

Next, an additional volume of the same uncured TIM was dispensed onto the top surface of the die, into the region confined within the TIM dam. A lid comprising coated metal base materials (for example Ni coated Cu plate) and having a top thickness of about 0.2-2.0 mm was then pressed down onto the additional uncured TIM with a maximum force of about 0.1-1.5 kgf.

Finally, the additional, uncured TIM was cured by exposing the entire package to thermal energy at a temperature of about 140-200° C. for a duration of about 1-3 hours. The resulting cured additional TIM would effectively communicate heat to the lid and the environment, from the die under operating conditions for the package.

Given the various applications and embodiments as described herein, the above description and illustrations should not be taken as limiting the scope of the present invention which is defined by the appended claims.

What is claimed is:

1. A method comprising:
dispensing a viscous material onto a top surface of a semiconductor die supported on a substrate;
pressing a package lid onto the viscous material; and
inhibiting a lateral spread of the viscous material with a structure.

2. The method of claim 1 wherein the viscous material comprises uncured Thermal Interface Material (TIM).

3. The method of claim 1 wherein the structure comprises a recess in the package lid.

4. The method of claim 3 wherein the recess comprises a first depth and further comprises a moat having a second depth.

5. The method of claim 1 wherein the structure comprises a polymer stopper in contact with the package lid.

6. The method of claim 1 wherein the structure comprises a polymer dam in contact with the top surface.

7. The method of claim 6 wherein:
the viscous material comprises uncured Thermal Interface Material (TIM); and
the polymer dam comprises cured TIM.

8. The method of claim 1 further comprising:
applying energy to the viscous material through the package lid.

9. The method of claim 8 wherein the energy comprises thermal energy.

10. The method of claim 8 wherein the energy comprises radiation.

11. An apparatus comprising:
a package lid having a spread inhibitor structure disposed proximate to an expected location of a side of a die.

12. The apparatus of claim 11 wherein the spread inhibitor structure comprises a recess of a first depth in the package lid.

13. The apparatus of claim 12 wherein the recess further comprises a moat having a second depth.

14. The apparatus of claim 11 wherein the spread inhibitor structure comprises a polymer stopper.

15. The apparatus of claim 11 further comprising:
a polymer in contact with the spread inhibitor structure; and
a package lid in contact with the polymer.

16. The apparatus of claim 15 wherein the polymer comprises a cured Thermal Interface Material (TIM).

17. An apparatus comprising:
a die having a top surface and supported on a substrate; and
a spread inhibitor structure disposed on the top surface proximate to a side of the die.

18. The apparatus of claim 17 wherein the spread inhibitor structure comprises a polymer dam.

19. The apparatus of claim 18 wherein the polymer dam comprises cured Thermal Interface Material (TIM).

20. The apparatus of claim 18 further comprising:
Thermal Interface Material (TIM) overlying the die and in contact with the polymer dam; and
a package lid in contact with the TIM.
